(19) United States
(12) Patent Application Publication
(10) Pub. No.: US 2022/0005728 A1
(43) Pub. Date: Jan. 6, 2022

(54) WAFER SUSCEPTOR AND CHEMICAL VAPOR DEPOSITION APPARATUS

(71) Applicant: ENKRIS SEMICONDUCTOR, INC., Suzhou (CN)

(72) Inventors: Kai LIU, Suzhou (CN); Kai CHENG, Suzhou (CN)

(21) Appl. No.: 17/478,638

(22) Filed: Sep. 17, 2021

Related U.S. Application Data
(63) Continuation of application No. PCT/CN2019/127086, filed on Dec. 20, 2019.

(51) Int. Cl. H01L 21/687; C23C 16/458

(52) U.S. Cl. CPC H01L 21/68785; C23C 16/4583; H01L 21/68757

(57) ABSTRACT

Disclosed are a wafer susceptor and a chemical vapor deposition apparatus, which solve a problem of a decrease in yield due to uneven wavelength of deposited epitaxial material caused by uneven heating during a wafer manufacturing process. The wafer susceptor includes: a wafer carrying groove; and two convex structures disposed at the bottom of the wafer carrying groove.

### CROSS-REFERENCE TO RELATED APPLICATIONS

This application is a continuation of International Application No. PCT/CN2019/127086, filed on Dec. 20, 2019, the entire contents of which are incorporated herein by reference.

### TECHNICAL FIELD

The present application relates to the technical field of process apparatus, particularly to a wafer susceptor and a chemical vapor deposition apparatus.

### BACKGROUND

At present, a metal-organic chemical vapor deposition (MOCVD) technique is usually used in a fabrication process of a wafer. A graphite disc is disposed in an MOCVD apparatus, several grooves are disposed on the upper surface of a graphite disc, and a piece of wafer is placed in a corresponding groove, a chemical reaction is carried out between the upper surface of the wafer and reaction gas from a spray-head by means of a heating unit of the MOCVD apparatus, thereby a corresponding epitaxial material layer is deposited on the upper surface of the wafer. There are stresses inside the wafer, such that the wafer is warped. Especially during the growth of the aluminum nitride, the periphery of the wafer is warped upward, which leads to the uneven heating of the wafer, and the temperature of the central area is higher than that of the periphery, which leads to the uneven wavelength of the prepared wafer, thereby reducing the yield.

### SUMMARY

In view of above problems, embodiments of the present application provide a wafer susceptor and a chemical vapor deposition apparatus, used for solving the problem of a decrease in yield due to inconsistent density of deposited epitaxial material caused by uneven heating during wafer manufacturing process.

An embodiment of the present application provides a wafer susceptor and a chemical vapor deposition apparatus including: at least one wafer carrying groove; and two convex structures respectively disposed at the bottom of the wafer carrying groove.

In an embodiment, the wafer carrying groove is circular in shape, and where the two convex structures are respectively disposed on two sides of the circle center of the wafer carrying groove.

In an embodiment, where there is a certain preset distance between the two convex structures.

In an embodiment, where two convex structures are respectively disposed at a position near to a quarter of the periphery of the bottom of the wafer carrying groove.

In an embodiment, where the number of the wafer carrying grooves is one of the following: 3, 6, 14 or 32.

In an embodiment, where the wafer susceptor is a graphite disc.

An epitaxial layer is formed on the wafer when the wafer is placed in the wafer carrying groove, the center area of the wafer is concaved towards the direction of the wafer carrying groove, and the periphery of the wafer is warped towards the direction away from the wafer carrying groove. With the wafer susceptor provided by embodiments of the present application, convex structures are disposed at the bottom of the wafer carrying groove, such that the wafer is more uniformly heated, and the wavelength of the epitaxial layer formed on the wafer is also more uniform.

### BRIEF DESCRIPTION OF DRAWINGS

FIG. 1 is a structure schematic diagram of a graphite disc provided by an embodiment of the present application.

FIG. 2a is a structure schematic diagram at the A-A′ section in FIG. 1 provided by an embodiment of the present application.

FIG. 2b is a structure schematic diagram of placing the wafer at the A-A′ section in FIG. 1 provided by an embodiment of the present application.

FIG. 3 is a structure schematic diagram of a wafer carrying groove provided by another embodiment of the present application.

FIG. 4 is a structure schematic diagram of a wafer carrying groove provided by another embodiment of the present application.

FIG. 5 is a structure schematic diagram of a wafer carrying groove provided by another embodiment of the present application.

FIG. 6 is a structure schematic diagram of vertical view of the convex structure provided by an embodiment of the present application.

### DETAILED DESCRIPTION OF THE EMBODIMENTS

The technical solutions in the embodiments of the present application will be clearly and completely described below which combine with reference to the accompanying drawings in the embodiments of the present application. Apparently, the described embodiments are some of the embodiments of the present application rather than all of the embodiments. Based on the embodiments of the present application, all other embodiments obtained by those of ordinary skill in the art without creative work shall fall within the protection scope of the present application.

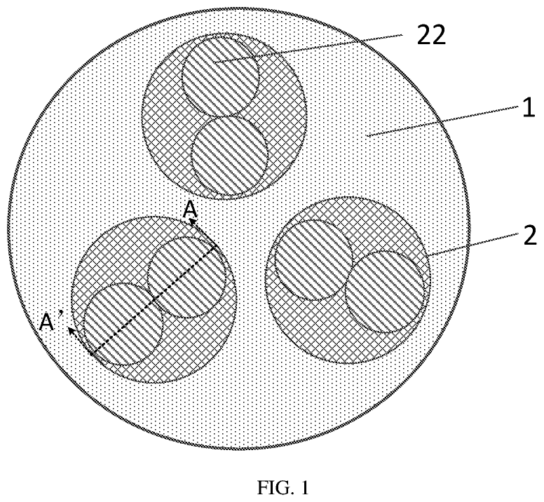

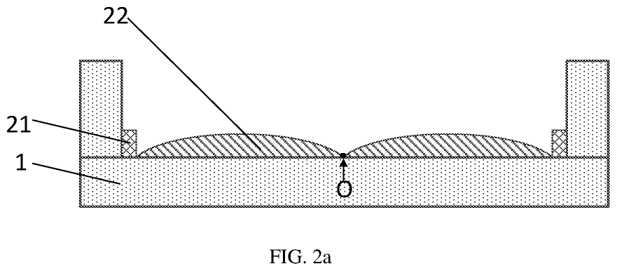

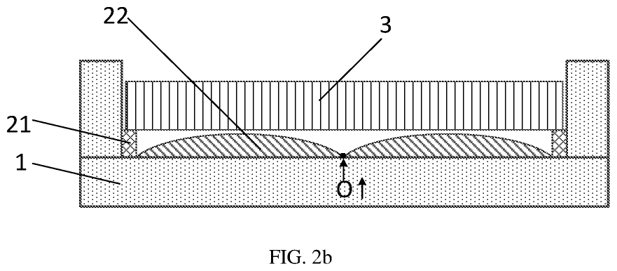

FIG. 1 is a structure schematic diagram of a graphite disc provided by an embodiment of the present application. FIG. 2a is a structure schematic diagram at the A-A′ section in FIG. 1 provided by an embodiment of the present application. FIG. 2b is a structure schematic diagram of placing the wafer at the A-A′ section in FIG. 1 provided by an embodiment of the present application.

As shown in FIG. 1, FIG. 2a and FIG. 2b, the wafer susceptor 1 includes at least one wafer carrying groove 2, and the wafer carrying groove 2 includes two convex structures 22 disposed at the bottom thereof. The two convex structures 22 are respectively disposed at two sides of the symmetric center O of the wafer carrying groove 2 (as shown in FIG. 2). In the embodiment shown in FIG. 1, the wafer carrying groove 2 is a circle in shape as an example, and thus the symmetric center O of the wafer carrying groove 2 is the center of the circle.

In the embodiment shown in FIG. 1 and FIG. 2, the two convex structures 22 are symmetrically designed with respect to the symmetric center of the wafer carrying groove 2, such that the wavelength of the prepared wafer is more uniform. the convex structure 22 can be disposed at a position of a half of the bottom of the wafer carrying groove 2 near the periphery of the bottom, that is, the area of the two convex structures 22 occupies a half of the area of the bottom of the wafer carrying groove.

In an embodiment of the present application, the wafer carrying groove 2 may include a step structure 21, and the step structure 21 is disposed in the wafer carrying groove 2 and is fit to the inner wall of the wafer carrying groove 2. The height of the step structure 21 is less than the height of the wafer carrying groove 2. The step structure 21 is used to support the wafer 3, so that there is a certain space between the wafer 3 and the bottom of the wafer carrying groove 2 to prevent the contact between the wafer 3 and the convex structures 22, so as to avoid certain damage to the wafer 3 due to the high temperature of the contact surface.

It should be understood that the step structure 21 may be a ring structure surrounding the bottom of the wafer carrying groove 2, or the step structure 21 may be several steps distributed at the bottom of the wafer carrying groove 2 according to a preset distance, and the specific shape of the step structure 21 is not limited in the embodiment of the present application.

In an embodiment of the present application, the maximum height of the convex structure 22 is less than the depth of the groove, and the maximum height of the convex structure 22 is also less than the height of the step structure 21 to prevent the convex structure 22 from contacting the wafer 3.

In the embodiment shown in FIG. 1, there are 3 wafer carrying grooves 2, which are generally suitable for 8-inch wafers 3. It should be understood that, the number of the wafer carrying grooves 2 can also be changed according to the size of the wafer 3. For instance, the number of the wafer carrying grooves 2 may be 6, 14, or 32 respectively to be applied to the size of wafers of 6 inches, 4 inches, and 2 inches. The number of the wafer carrying grooves 2 is not specifically limited in the embodiment of the present application.

It should be understood that the wafer susceptor 1 may be a graphite disc, or the wafer susceptor 1 may also be made of other materials, and the specific material of the wafer susceptor 1 is not limited in the embodiment of the present application.

During the preparation process of the wafer 3, the central area of the wafer 3 will be concaved and the periphery of the wafer 3 will be warped. The convex structures 22 are disposed on two sides of the center of a circle, such that the heated temperature on the surface of the entire wafer 3 is more uniform, and thereby the wavelength of the epitaxial layer formed on the wafer 3 is also more uniform.

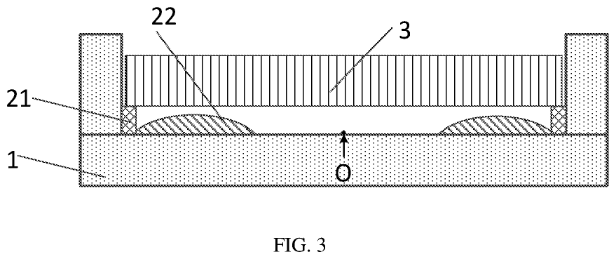

In the above embodiments, the two convex structures 22 are disposed continuously; the distance between the two convex structures 22, however, is not particularly limited in the present application. FIG. 3 is a structure schematic diagram of a wafer carrying groove 2 provided by another embodiment of the present application, and as shown in FIG. 3, the convex structure 22 can be disposed at a position of a quarter of the bottom of the wafer carrying groove 2 near the periphery of the bottom, that is, the area of the two convex structures 22 occupies an eighth of the area of the bottom of the wafer carrying groove. There is a preset distance between the two convex structures 22, and the distance may be determined according to the warpage of the wafer.

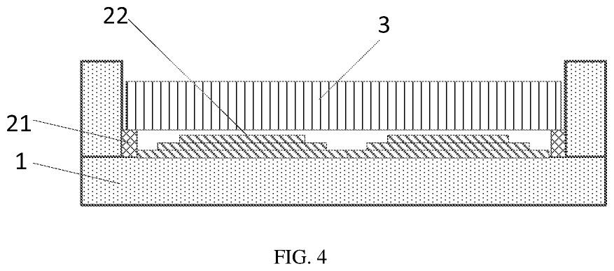

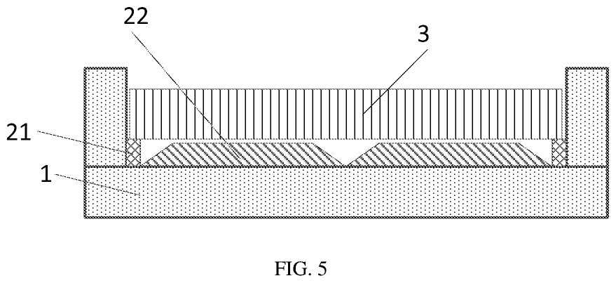

The convex structure 22 have a variety of shapes, it should be understood that, it may have either a circular arc cross-section as shown in FIG. 3, or a step-shaped cross-section as shown in FIG. 4, or a trapezoidal cross-section as shown in FIG. 5, and this is not particularly limited in the present application.

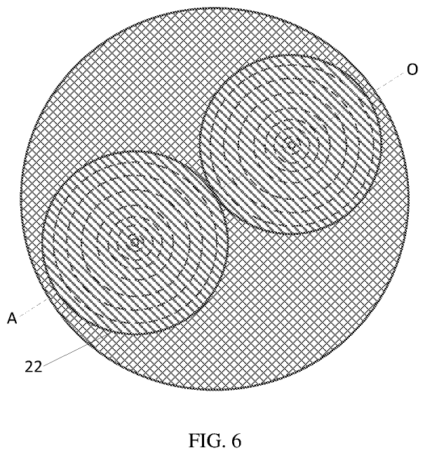

FIG. 6 is a structure schematic diagram of a vertical view of the convex structure provided by an embodiment of the present application. The dotted line in FIG. 6 is a contour map, the center of the convex structure 22 is the highest point in the contour map, and the height of the convex structure 22 is getting smaller and smaller from the center to the periphery of the groove. It should be understood that the contour map of the convex structure 22 is provided in order to help those skilled in the art understand a three-dimensional shape of the convex structure 22 of the present application, and the present application does not limit a specific change of the height h of the convex structure 22. The contour lines in the vertical view of the convex structure 22 may also be elliptically, and the present application does not limit the vertical view of the convex structure 22.

Those described above are merely preferred embodiments of the present application, and by no way to limit the present application thereto. Any modifications, equivalent substitution, etc. within the spirit and principle of the present application are covered by the protection scope of the present application.

What is claimed is:

1. A wafer susceptor, comprising:
at least one wafer carrying groove, wherein the wafer carrying groove has a circular shape; and
two convex structures disposed at a bottom of the wafer carrying groove, wherein the two convex structures are respectively disposed at two sides of a circle center of the wafer carrying groove.

2. The wafer susceptor according to claim 1, wherein there is a preset distance between the two convex structures.

3. The wafer susceptor according to claim 2, wherein the two convex structures are respectively disposed at a position of a quarter of the bottom of the wafer carrying groove near to a periphery of the bottom of the wafer carrying groove.

4. The wafer susceptor according to claim 2, wherein the two convex structures are respectively disposed at a position of a half of the bottom of the wafer carrying groove near to a periphery of the bottom of the wafer carrying groove.

5. The wafer susceptor according to claim 1, wherein each of the two convex structures is a convex structure with multiple layers.

6. The wafer susceptor according to claim 1, wherein a number of the wafer carrying grooves is one of the following: 3, 6, 14 or 32.

7. The wafer susceptor according to claim 1, wherein the wafer susceptor is a graphite disc.

8. The wafer susceptor according to claim 1, wherein the two convex structures are symmetrically designed with respect to a symmetric center of the wafer carrying groove.

9. The wafer susceptor according to claim 1, wherein the wafer carrying groove comprises a step structure, and the step structure is disposed in the wafer carrying groove and is fit to an inner wall of the wafer carrying groove.

10. A chemical vapor deposition apparatus, comprising:
a wafer susceptor, the wafer susceptor comprising:
at least one wafer carrying groove, wherein the wafer carrying groove has a circular shape; and
two convex structures disposed at a bottom of the wafer carrying groove, wherein the two convex structures are respectively disposed at two sides of a circle center of the wafer carrying groove.

11. The chemical vapor deposition apparatus according to claim 10, wherein there is a preset distance between the two convex structures.

12. The chemical vapor deposition apparatus according to claim 11, wherein the two convex structures are respectively disposed at a position of a quarter of the bottom of the wafer carrying groove near to a periphery of the bottom of the wafer carrying groove.

13. The chemical vapor deposition apparatus according to claim 10, wherein each of the two convex structures is a convex structure with multiple layers.

14. The chemical vapor deposition apparatus according to claim 10, wherein a number of the wafer carrying grooves is one of the following: 3, 6, 14 or 32.

15. The chemical vapor deposition apparatus according to claim 10, wherein the wafer susceptor is a graphite disc.

16. The chemical vapor deposition apparatus according to claim 10, wherein the two convex structures are symmetrically designed with respect to a symmetric center of the wafer carrying groove.

17. The chemical vapor deposition apparatus according to claim 10, wherein the wafer carrying groove comprises a step structure, and the step structure is disposed in the wafer carrying groove and is fit to an inner wall of the wafer carrying groove.
